(19) United States
(12) Patent Application Publication
(10) Pub. No.: US 2014/0072008 A1
(43) Pub. Date: Mar. 13, 2014

(54) COLOR CENTERS AFFECTED BY MAGNETIC FIELDS TO PRODUCE LIGHT BASED ON LASING

(71) Applicants: Andrei Faraon, Menlo Park, CA (US); Charles M. Santori, Palo Alto, CA (US); Raymond G. Beausoleil, Redmond, WA (US)

(72) Inventors: Andrei Faraon, Menlo Park, CA (US); Charles M. Santori, Palo Alto, CA (US); Raymond G. Beausoleil, Redmond, WA (US)

(21) Appl. No.: 13/614,496

(22) Filed: Sep. 13, 2012

(51) Int. Cl. H01S 5/02; H01S 5/04

(52) U.S. Cl. 372/45.01; 372/44.01; 372/69

(57) ABSTRACT

A resonant cavity, including a gain medium and a color center formed in the gain medium, is to be used for lasing in a system. The color center includes a lower laser level based on a plurality of spin states that are affected by a magnetic field. A gain associated with the system depends on the plurality of spin states. The system is to produce light based on lasing by the resonant cavity in response to application of pump energy to pump the color center. An intensity of the produced light is affected by the magnetic field in the presence of microwaves.

### BACKGROUND

A point defect in diamond, known as a nitrogen-vacancy (NV) center, exhibits magnetic resonances and can be used as a magnetometer. However, sensitivity for this type of magnetometer is limited, due to the limited amount of light that can be collected from a luminescing NV center, such as an NV center in bulk diamond or diamond nano-particles. The amount of photoluminescence in such systems is limited by the spontaneous emission rate of nitrogen-vacancy centers.

### BRIEF DESCRIPTION OF THE DRAWINGS/FIGURES

FIG. 1 is a block diagram of a system including a color center according to an example.

FIG. 2 is a block diagram of a system including a color center according to an example.

FIG. 3 is a block diagram of a system including a color center according to an example.

FIG. 4 is an energy diagram associated with a system including a color center according to an example.

FIG. 5 is an energy diagram associated with a system including a color center according to an example.

FIG. 6 is an energy diagram associated with a system including a color center according to an example.

FIG. 7 is a diagram illustrating luminescence associated with an ensemble of color centers according to an example.

FIG. 8 is a flow chart for producing light based on a color center according to an example.

### DETAILED DESCRIPTION

Magnetometry may be performed with an emitter (e.g., a color center) that has a ground state composed of multiple states whose splitting is magnetic field dependent, and where the multiple states exhibit different output by the color center. The output of color centers may change with application of a magnetic field under certain conditions, such as during application of a microwave field. Examples may provide Optically Detected Magnetic Resonance (ODMR), including continuous-wave ODMR. The luminescence signal from color centers may be enhanced through the use of lasing, where a gain medium includes color centers and has been placed in a resonant cavity. The laser action may be taken advantage of to provide a much more sensitive detector. For example, the sensitivity of a magnetometer may depend on the amount of collected light. By achieving lasing, it is possible to rely on stimulated emission, rather than spontaneous emission, and achieve significant amplification of the signal (e.g., output from a color center). Thus, examples may use stimulated emission, enhanced with a cavity, to create a laser to detect output from color centers. Lasing may be enabled, for example, by coupling the color centers to optical cavities, to increase the sensitivity of magnetometers. Further, examples provide output with enhanced spatial coherence, and enable produced light to be channeled into an optical subsystem, such as a waveguide, in contrast to non-lasing systems based on merely collecting spontaneous emission.

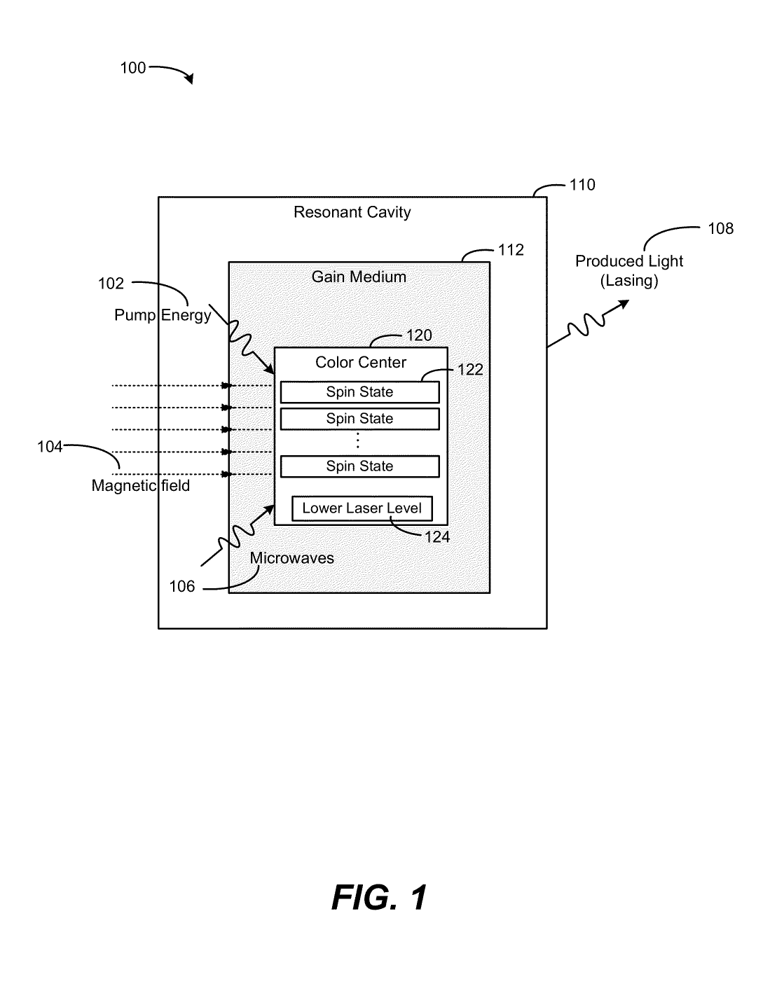

FIG. 1 is a block diagram of a system 100 including a color center 120 according to an example. The system 100 also includes a resonant cavity 110 and gain medium 112. The color center 120 may be associated with a plurality of spin states 122 and a lower laser level 124. The system 100 can provide produced light 108 based on lasing in view of pump energy 102, magnetic field 104, and/or microwaves 106.

The color center 120 is associated with a plurality of spin states 122, which may be referred to as spin (sub) levels, and a lower laser level 124. The lower laser level 124 is identified as the lower level used to define the population inversion associated with lasing for system 100. The lower laser level 124 may be a spin state 122. The lower laser level 124 may be a true “ground state” or ensemble of ground state(s) that are the spin levels that color center 120 would be pumped from (e.g., based on pump energy 102). The plurality of spin states 122 associated with the lower laser level 124 are affected by magnetic field 104.

The plurality of spin states 122 may be associated with energy spacing between the spin states 122. Applying magnetic field 104 may change the energy spacing between the spin states 122. Depending on which state, different laser output may be provided when applying a microwave field (e.g., microwaves 106). Thus, by detecting output of the color center 120, it is possible to infer information regarding the magnetic field 104. If the plurality of spin states 122 exhibit a plurality of different outputs, the spin states 122 also may provide gain at different wavelengths.

Detection of output from the color center 120 may be enhanced based on lasing. The lasing is based on materials (e.g., color center 120) that exhibit ODMR, producing a gain that depends on the applied magnetic field 104 and/or microwaves 106 (i.e., providing an ODMR signal).

The resonant cavity 110 enables system 100 to lase, such that produced light 108 has increased availability due to stimulated emission. Lasing may provide other benefits, such as emitting produced light 108 in a single mode to facilitate optical collection (e.g., using a single-mode waveguide or other optical subsystem). Other examples may emit produced light 108 in multiple modes (i.e., examples are not limited to single mode). To lase, a gain medium 112, such as diamond or silicon carbide (SiC), may be associated with a resonant cavity 110, such as an optical cavity. For example, the gain medium 112 may be formed directly into a resonant cavity 110. The resonant cavity 110 may include other types of cavities, such as Bragg gratings coupled with a single mode diamond waveguide, or otherwise sandwiching the gain medium 112 between two mirrors.

For system 100 to lase, the associated gain of the system 100 is to be higher than the losses associated with the system 100. For a resonant cavity 110 having a quality factor of 10⁴ (e.g., for a resonant cavity 110 formed in single crystal diamond), the associated gain may be achieved based on a minimum number of color centers (e.g., NV centers for a diamond gain medium 112) of approximately ˜10⁵/micron³ (for lasing through vibronic states).

Lasing may enhance the sensitivity of the laser magnetometer system 100, and may achieve approximately ˜1 nTVsqrt(Hz) sensitivity. Enhanced sensitivity enables various applications, at levels not previously achievable, such as detection of electrical neuron signals or other sensitive magnetic field sensing applications.

The gain medium 112 can be used to support at least one color center 120. The gain medium 112 may include a variety of color centers 120 that may be distributed throughout the gain medium 112 according to various arrangements, such as a uniform distribution. The gain medium 112 may be diamond, SiC, and/or various wide-bandgap, group IV semiconductor materials. The gain medium 112 may exhibit dielectric and even magnetic properties, and may be used to form a laser cavity (resonant cavity 110).

The color center 120 is to provide the actual gain for the gain medium 112, and the color center 120 is embedded in the gain medium 112. The color center 120 may be a nitrogen vacancy (NV) center in examples where the gain medium 112 is diamond, and the color center 120 may be a divacancy in examples where the gain medium 112 is silicon carbide (SiC). A divacancy may be formed by a missing silicon atom whose nearest carbon neighbor is also missing. Other forms of NV centers and/or divacancies may be used.

In an example, the gain medium 112 is a single-crystal diamond. The single crystal diamond may be engineered to contain a high concentration of color centers 120, which may be NV centers in the single-crystal diamond gain medium 112. The color centers 120 may emit red light output when excited with pump energy 102 (e.g., green light). Stimulated emission, and thus lasing, may be achieved with sufficient concentration of color centers 120, high quality resonant cavity 110, and sufficient pump energy 102. When lasing is achieved, the amount of output emitted from the color centers 120 increases dramatically.

A nitrogen vacancy center (color center 120) may be formed in diamond by removing two neighboring carbon atoms in the diamond lattice, and replacing only one of them with a nitrogen atom. A divacancy center (color center 120) may exist in SiC, and also may exist in diamond (e.g., two missing carbon atoms at nearest neighbor lattice sites). Divacancies may correspond to spin-1 ground states that can be spin-polarized with incident light.

Pump energy 102 may be optical, electrical, or other forms of energy, that may be absorbed by and/or transferred to the color center 120. The resonant cavity 110 then may provide feed-back, and the gain medium 112 may serve as an amplifier, to provide lasing. The feedback caused by the resonant cavity 110 allows the gain medium 112 to amplify color center 120 output in a coherent manner to lase.

The magnetic field 104 is to affect the energy splitting, i.e., the energy difference, between the spin states 122. Magnetometers based on color centers 120 rely on changes in the intensity of a color center's output as a function of the magnetic field 104. The magnetic field 104 is to affect system 100 in the presence of the microwaves 106.

The microwaves 106 may be applied to the system 100 as, e.g., a microwave field having a frequency, to observe corresponding changes in output of the color centers 120. The frequency of microwaves 106 may correspond to the energy level structure of the color centers 120. The color center 120 may be associated with multiple energy levels, and a frequency of the microwaves 106 may be directly related to the difference of the energy levels. Microwave excitation may be used to depolarize the spins that are precessing at the same frequency as determined by the magnetic field 104. The depolarization affects the system gain and how much produced light 108 is emitted from the system 100. Exposure to microwaves 106 may affect the populations of the plurality of spin states 122 associated with the lower laser level 124. However, when the system 100 is then excited by the pump energy 102, distribution of spin states 122 in the excited laser levels may change.

Microwaves 106 may be applied continuously. Other techniques may include sequences of pulses of microwave excitation, and changing a delay between pulses of microwave excitation. Thus, a relationship between the magnetic field 104 and the microwaves 106 may be developed based on sweeping, pulsing, delaying, or otherwise varying the microwaves 106.

The system 100 therefore enables produced light 108 to be based on lasing. The gain produced may be dependent on the plurality of spin states 122. The produced light 108 may exhibit different gain for different spin states 122, which may be affected by magnetic field 104, thus providing a laser magnetometer.

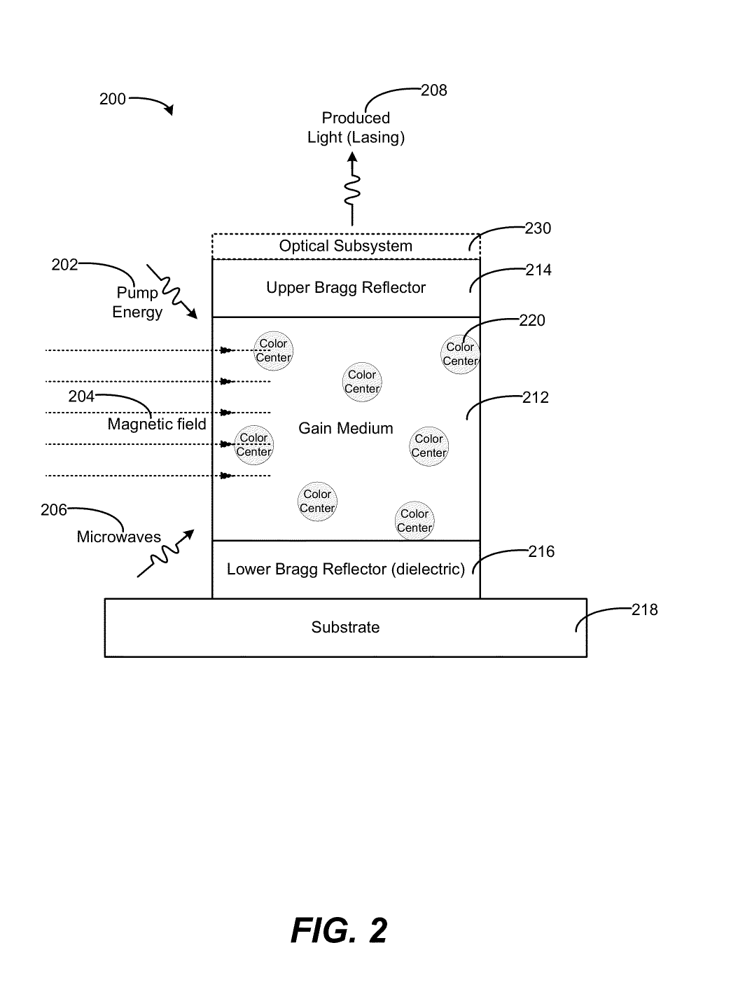

FIG. 2 is a block diagram of a system 200 including a color center 220 according to an example. The system 200 also includes gain medium 212, upper reflector 214, lower reflector 216, and substrate 218. The system 200 can provide produced light 208 based on pump energy 202, magnetic field 204, and/or microwaves 206. The system 200 may include an optical subsystem 230.

System 200 illustrates an example of a vertical-cavity surface-emitting laser (VCSEL) based on color centers 220 affected by magnetic field 204. Produced light 208 may be provided based on lasing and coupling-to-free-space. The system 200 may be provided as a diamond pillar supported by substrate 218. A Bragg reflector of some kind (e.g., to serve as a dielectric) may be provided as the lower reflector 216. A grating and/or Bragg reflector may be provided as the upper reflector 214. The reflectors 214, 216, and the gain medium 212, thus provide a resonant cavity including color centers 220. The resulting system 200 may operate like a VCSEL to generate produced light 208 based on lasing.

Optical subsystem 230 is to couple the produced light 208 for output. As illustrated, the optical subsystem 230 is an output coupler to free space. In alternate examples, the optical subsystem 230 may be provided as a planar waveguide for a planar cavity and/or coupling. The optical subsystem 230 may be a non-waveguide structure to couple light, such as a lens, grating structure, or other structure for collecting produced light 208 and/or free-space coupling.

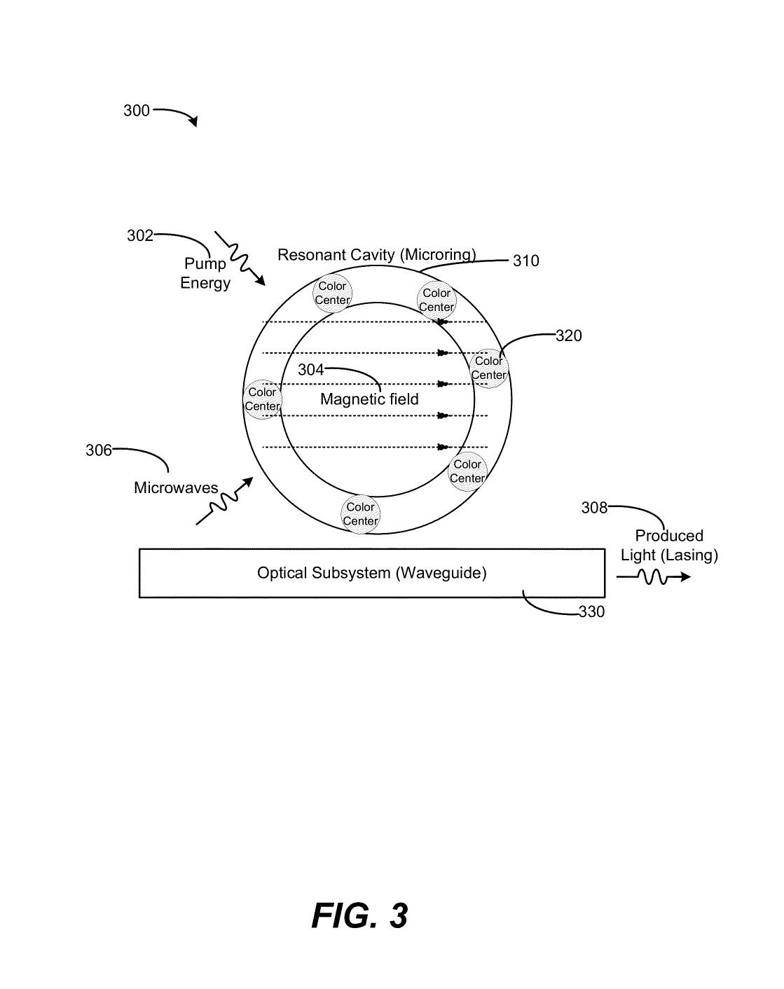

FIG. 3 is a block diagram of a system 300 including a color center 320 according to an example. The system 300 also includes resonant cavity 310 and optical subsystem 330. The system 300 can provide produced light 308 based on pump energy 302, magnetic field 304, and/or microwaves 306.

The resonant cavity 310 may be a microring to enable lasing, based on confining light (emitted by the color centers 320) to circulate around the microring until the light is coupled out via the optical subsystem 330 (e.g., based on waveguide coupling). The light from the resonant cavity 310 can be immediately coupled to optical subsystem 330 (waveguide) and then to an optical fiber, providing efficient and compact coupling for emitting produced light 308 based on lasing. The optical subsystem 330 may include a single-mode waveguide, for simplicity, though examples may use waveguides that are not single mode, and may be associated with mode competition. Thus, system 300 may be provided in a compact form-factor for magnetic sensing.

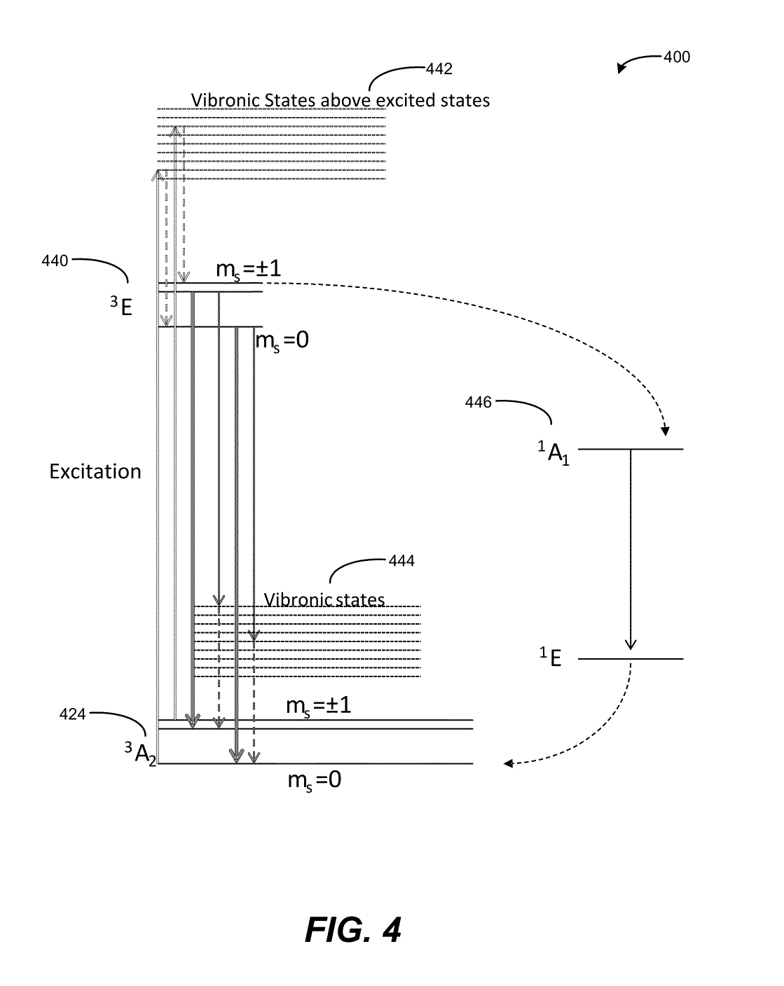

FIG. 4 is an energy diagram 400 associated with a system including a color center according to an example. The energy diagram 400 illustrates excitation and decay associated with various states, including ground states 424 associated with a lower laser level, vibronic states 444, excited states 440, vibronic states above excited states 442, and ¹A₁ state 446.

A lower laser level 424, as well as an upper laser level, may be associated a plurality of spin states (e.g., spin states 122 shown in FIG. 1). Arrows are used to illustrate possible excitation and possible decay paths, and whether lasing involves going through vibronic states 444 and/or vibronic states above excited states 442. Various paths shown in the energy diagram 400 may result in lasing, while providing a mechanism for optically detected magnetic resonance.

In an example, excitation may be based on a green laser having a wavelength of 532 nm at 2 mW. Excitation may be based on other pump energies, as appropriate for a given system 400. The ground states 424 and excited states 440 may include a plurality of spin states, including mₛ=±1 and mₛ=0. When in the mₛ=0 spin state, optical transitions are mainly cycling, which means that while exciting the system with pump energy, the system will get excited from mₛ=0 ground state 424 to mₛ=0 excited state 440, and then decay back down to mₛ=0 ground state 424 by emitting a photon. The system may continue getting reexcited according to this cycle. However, if the system is in the mₛ=±1 spin state, there is a possibility, once excited to the excited states 440, that the system will decay through singlet levels, which are shown on the right of FIG. 4 associated with the ¹A₁ state 446. If decaying through the singlet levels, the system gain may be reduced. Thus, the lasing depends on what spin states are involved. As set forth above, microwaves and a magnetic field may work together to change the spin populations such that the system may not lase brightly or may not lase at all. Because the lasing is dependent on the magnetic field for a particular microwave frequency, the system may infer and/or detect a magnetic field.

Various aspects of the system may be referred to as an upper laser manifold, lower laser manifold, ground state, i.e., lower pump manifold, and excited state, i.e., the upper pump manifold. System 400 may be a quasi three-level system, where three spin levels are shown, and the lower laser level is depopulated by pumping the system out of a lowest quantum state. System 400 may be a four-level system, lasing with sidebands, depending on the level of the lower and/or upper laser levels.

At room temperature, some transitions may not be spectrally resolved within a zero-phonon line. Rapid phonon assisted relaxation between two orbital branches (e.g., between ³Eₓ and ³E_{y} excited state manifolds), i.e., orbital relaxation, may be so fast that there is a motional averaging and the excited states may appear as if there were a single orbital state. FIG. 4 is approximating such a room temperature condition.

In order for lasing to occur, population inversion is to be created, resulting in gain to be stored in an amplifier (e.g., resonant cavity). A population inversion that is created is to be large enough such that the gain in the laser medium (e.g., for a round trip of generated light through the amplifier) exceeds losses that the generated light might see during the round trip, enabling a feedback system. This is relatively straight forward to achieve when lasing occurs using the vibronic states 444 and/or the vibronic states above excited states 442, because these states are not occupied. By manipulating the coupling between upper levels and lower levels, the conditions to create the population inversion are correspondingly changed. Placing population in the excited state 440 may create population inversion. Inversion also may be achieved with respect to the ground states 424, but in such a situation more than half of the population is to be excited from the ground states 424.

In an example, the color centers may be provided as NV centers. The ground state of an NV center may have three states (a spin triplet), and the splitting between mₛ=0 and mₛ=±1 may be approximately 2.87 GHz. The output of the NV center is different when it is in the state mₛ=0 and mₛ=±1. When in state mₛ=0, the excited NV center emits a photon, while when in state mₛ=±1, the excited NV center can either emit a photon or (in about 30% of the cases) go into the state ¹A₁ which is mostly dark.

In an example, assume that the color center output, when in state mₛ=0, is I₀. When in state mₛ=±1, the output is I₁. When the NV center goes into the ¹A₁ state 446, the NV center will likely decay to the mₛ=0 state. The ¹E state may have approximately equal chances to decay to the various triplet ground states, including mₛ=±1 and mₛ=0. Several cycles may be used to get very high probability into mₛ=0. Thus, if the system begins in the mₛ=±1 state, it will rapidly (on the order of microsecond(s)) transition into the mₛ=0 state. Thus, under continuous excitation, the system emits I₀ regardless of the initial state. A microwave field, e.g., at approximately 2.87 GHz, may be applied such that the NV centers are constantly mixed in a 50/50 superposition of mₛ=0 and mₛ=±1, such that the output intensity is (I₀+I₁)/2. If a magnetic field changes the splitting between mₛ=0 and mₛ=±1, the NV centers quickly polarize to mₛ=0 and I₀ is detected. This is one way the magnetic field may be sensed. Additional information associated with the magnitude of the magnetic field may be derived by sweeping a frequency of the microwaves, and/or monitoring changes in output.

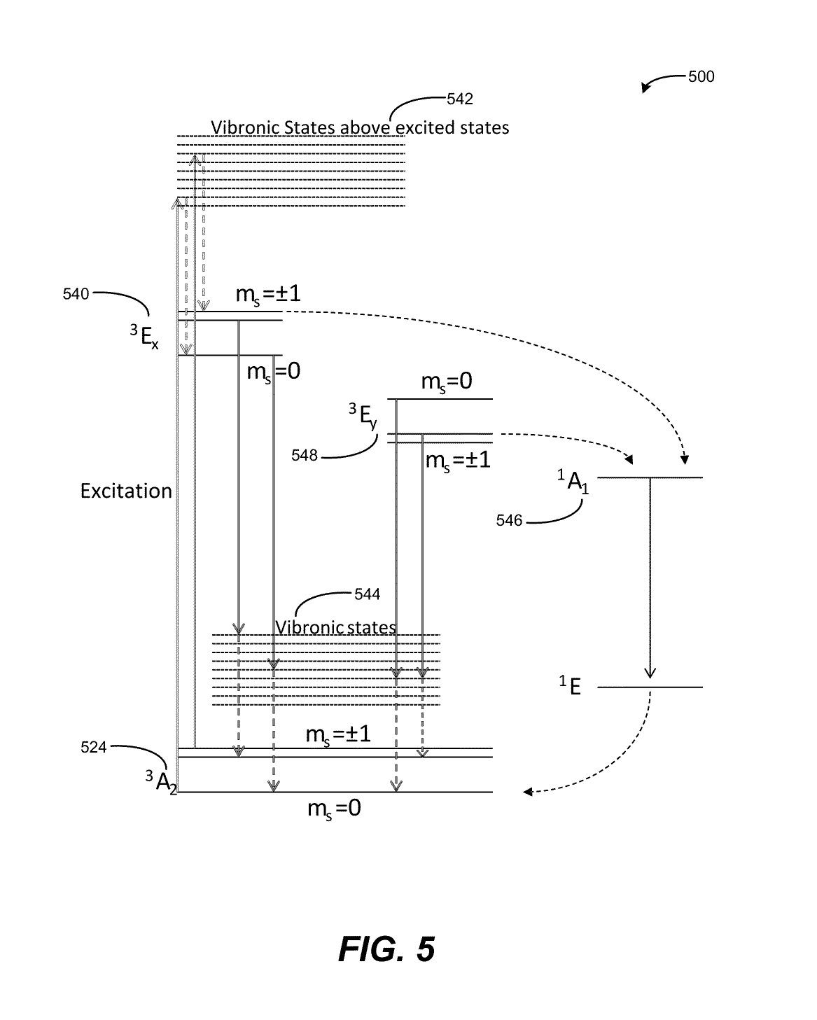

FIG. 5 is an energy diagram 500 associated with a system including a color center according to an example. The energy diagram 500 illustrates excitation and decay associated with various states, including ground states 524 associated with a lower laser level, vibronic states 544, excited states 540, vibronic states above excited states 542, ³E_{y} states 548, and ¹A₁ state 546. FIG. 5 illustrates excitation and decay paths, as illustrated by arrows.

FIG. 5 shows separate orbital states for the excited states, without motional averaging as shown in FIG. 4. Lasing is shown occurring through phonon (vibronic) states and/or decay, represented by the downward arrows transitioning at the vibronic states 544 from solid-arrows to dashed-arrows. As in the example of FIG. 4, excitation may be based on a green laser (having a wavelength of 532 nm, for example). The energy levels and optical transitions are shown for a negatively-charged nitrogen-vacancy center in diamond, with a strain splitting between the Eₓ and E_{y} excited orbital states. The vibronic states 544 and/or vibronic states above excited states 542 may decay directly to ground states 524.

In contrast to FIG. 4, FIG. 5 shows separate ³Eₓ and ³E_{y} excited state manifolds (e.g., excited states 540 and ³E_{y} states 548). In the lower E_{y} branch (³E_{y} states 548), each of those states will have some transition strengths to both ground states 524. The dominant transition strength may be from mₛ=0 to mₛ=0, and from mₛ=±1 to mₛ=±1.

In an example, the color centers may be NV centers. An NV center may have a trigonal symmetry (point group C_{3V}). The ground states 524 (e.g., ³A₂) may have an orbital singlet, spin triplet structure having a 2.87 GHz splitting between the mₛ=0 and mₛ=±1 spin sublevels. These states may be connected by optical transitions to a set of six excited states with an orbital doublet, spin triplet structure. Due to random strain fields present in the gain medium crystal, the orbital states denoted as Eₓ and E_{y} are typically nondegenerate. Here, x and y refer to principal axes in a plane perpendicular to the NV center, with an angle determined by the strain tensor. The magnitude of this splitting depends on the crystal quality, and may be on the order of 10 GHz (diamond). The optical transitions involving the Eₓ and E_{y} orbital states follow linear polarization selection rules. For the higher-energy orbital branch, the mₛ=0 transition may primarily be spin-conserving, useful as a cycling transition for spin readout. In the lower-energy orbital branch, non-spin-conserving transitions may be obtained, useful for optical spin manipulation or for schemes based on Raman scattering.

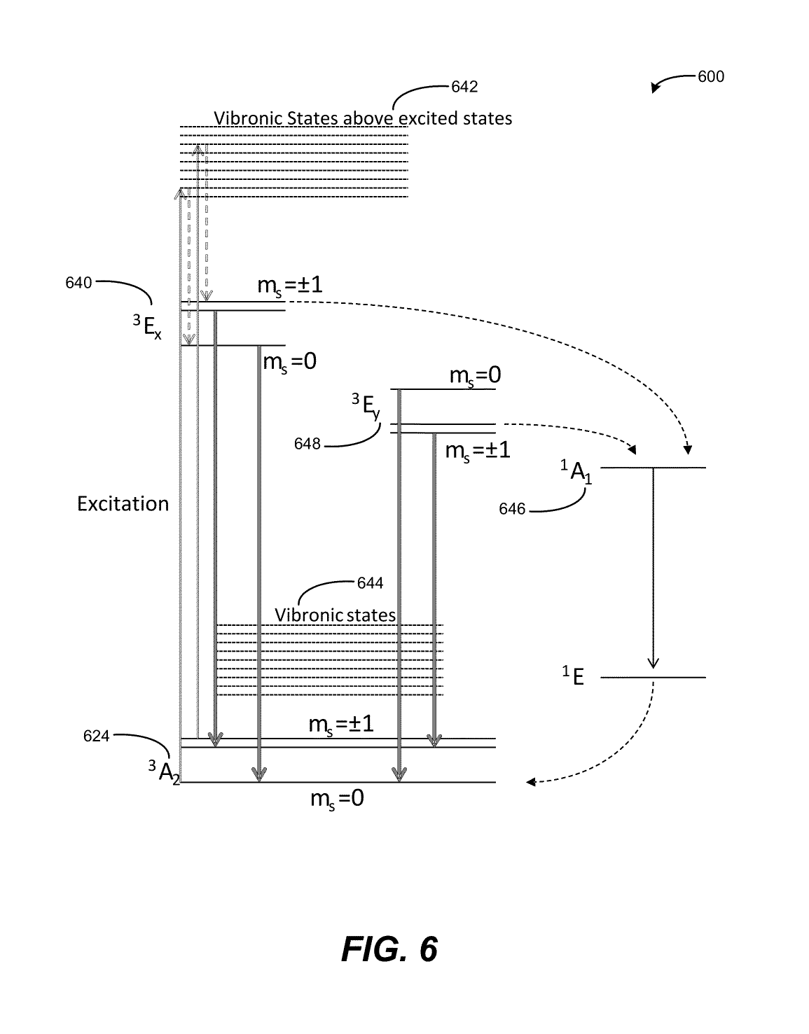

FIG. 6 is an energy diagram 600 associated with a system including a color center according to an example. The energy diagram 600 illustrates excitation and decay associated with various states, including ground states 624 associated with a lower laser level, vibronic states 644, excited states 640, vibronic states above excited states 642, ³E_{y} states 648, and ¹A₁ state 646.

In contrast to FIG. 5, FIG. 6 illustrates lasing through the ground state(s) 642. Direct decay to ground states 642, the zero phonon line, is represented by solid arrows passing through the vibronic states 644. Other principles described with respect to the examples above are applicable where relevant, e.g., operation of the ¹A₁ state 646.

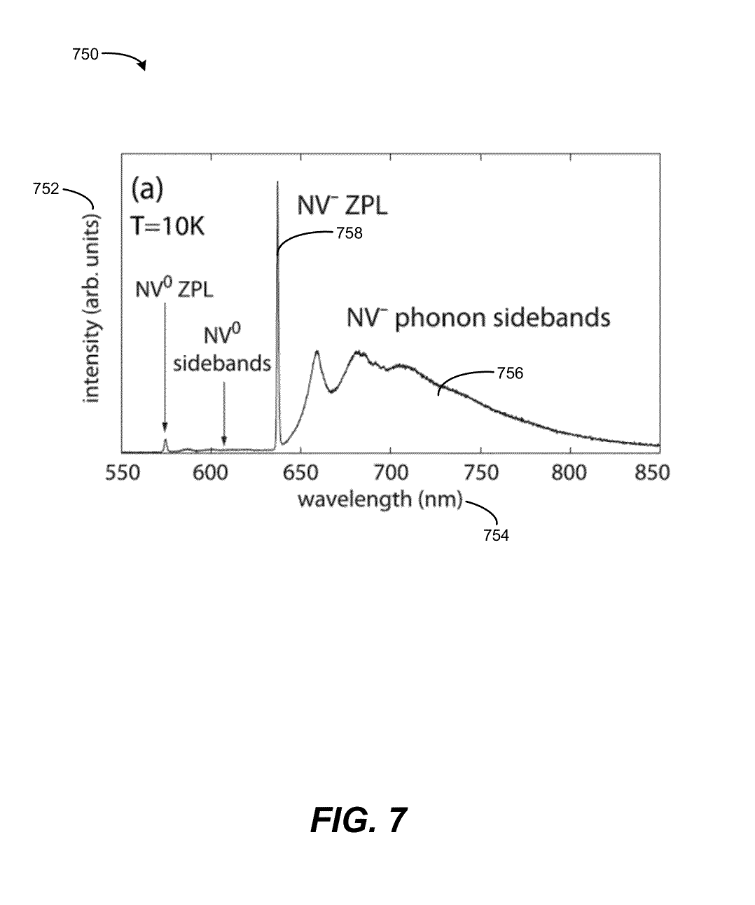

FIG. 7 is a diagram 750 illustrating luminescence associated with an ensemble of color centers according to an example. Diagram 750 illustrates intensity 752 as a function of wavelength 754, and includes negatively charged nitrogen vacancy (NV⁻) zero-phonon line (ZPL) 758 and NV⁻ phonon sidebands 756. More specifically, diagram 750 shows a photoluminescence (PL) spectrum obtained from a dense ensemble of NV centers at liquid helium temperature (10 K) under nonresonant excitation (532 nm). The zero-phonon lines of NV⁰ and NV⁻ at 575 nm and 637 nm, respectively, are evident. At room temperature, the PL spectrum would show a broadening of the zero-phonon line to a width of several nanometers.

In contrast to showing lasing associated with a resonant cavity, diagram 750 shows luminescence of an ensemble of color centers (e.g., intensity 752 as a function of wavelength 754). More specifically, diagram 750 shows luminescence of an NV center in a diamond crystal. The luminescence can show how much gain may be expected for a gain medium/color center, including what wavelength will provide a given gain, and what wavelength might be desirable for initiating lasing (e.g., a wavelength with a high intensity).

The sharp peak below 650 nm is the transition from the E states, such as transitions from the Eₓ, E_{y} states to the A₂ states directly, as shown in thick solid arrows shown in FIGS. 4-6. The broad hump from approximately 650 nm to 850 nm represents light that is emitted through the vibronic states. There are many vibronic states, providing a continuum that may emit the light in the hump from approximately 650 nm to 850 nm. The peak, labeled NV⁻ ZPL 758, may be from mₛ=±1 or mₛ=0, because the associated individual representations on the diagram 750 would be too narrow to be resolved independently on the illustrated spectrum. The narrow line of the peak NV⁻ ZPL 758, corresponding approximately to 637 nm, is associated with transitions both from mₛ=±1 and mₛ=0, within that narrow line. The NV center may capture another electron and form a negatively charged NV. The NV center is optically bright, and emits radiation in red (˜630-800 nm). It is usually excited with green light (532 nm) but almost any visible wavelength below 630 nm is effective.

The diagram 750 shows that lasing may be enabled anywhere from approximately 637 nm to 800 nm. Lasing through the vibronic states would involve a wavelength 754 in the broad hump, and lasing through the zero phonon line would involve a wavelength 754 within the sharp peak at approximately 637 nm.

Based on resonant cavity and other characteristics chosen to establish lasing, a sharp peak in intensity may be created (not shown), to be located typically between approximately 637 nm and 800 nm, corresponding to the chosen lasing wavelength 754. In an example, a desired lasing intensity may be chosen (which may be either in the zero phonon line or the vibronic states) corresponding to a resonant cavity, and a microwave frequency may be applied along with a pump energy and magnetic field, and the intensity 752 for lasing should be achieved.

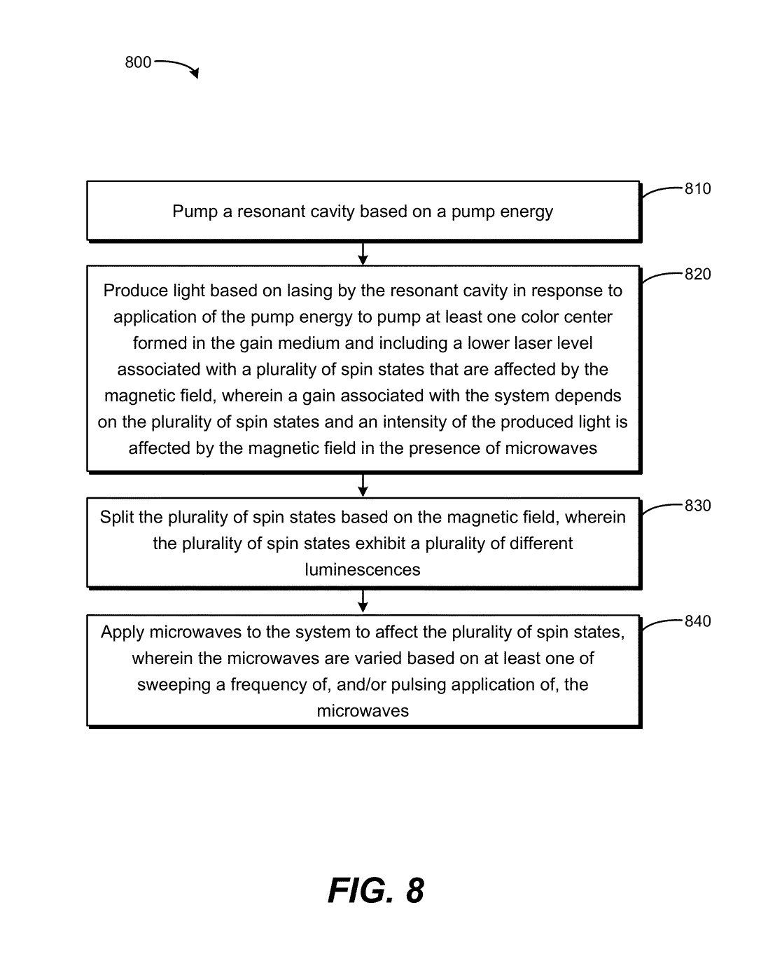

FIG. 8 is a flow chart 800 for producing light based on a color center according to an example. In block 810, a resonant cavity is pumped based on a pump energy. For example, a green light with a visible wavelength approximately 630 nm or below may be used to optically pump the resonant cavity, to excite a color center. In block 820, light is produced based on lasing by the resonant cavity in response to application of the pump energy to pump at least one color center. The at least one color center is formed in the gain medium and includes a lower laser level associated with a plurality of spin states that are affected by the magnetic field. A gain associated with the system depends on the plurality of spin states and an intensity of the produced light is affected by the magnetic field in the presence of microwaves. For example, the microwaves and resonant cavity may be chosen to cause lasing associated with the zero phonon line and/or the vibronic states, when pumped in the presence of a magnetic field. In block 830, the plurality of spin states are split based on the magnetic field, wherein the plurality of spin states exhibit a plurality of different luminescences. For example, the magnetic field affects output such that lasing enables inference of the magnetic field. In block 840, microwaves are applied to the system to affect the plurality of spin states, wherein the microwaves are varied based on at least one of sweeping a frequency of, and/or pulsing application of, the microwaves.

Generally, as used in the specification and claims herein, the singular forms “a,” “an,” and “the” include plural references unless the context clearly dictates otherwise.

1. A system comprising:
a resonant cavity including a gain medium, wherein the resonant cavity is bounded by surfaces of the gain medium; and
a color center, formed in the gain medium, including a lower laser level based on a plurality of spin states that are affected by a magnetic field, wherein a gain associated with the system depends on the plurality of spin states, and the system is to produce light based on lasing by the resonant cavity in response to application of pump energy to pump the color center, wherein an intensity of the produced light is affected by the magnetic field in the presence of microwaves.

2. The system of claim 1, wherein the gain medium is formed of single-crystal diamond.

3. The system of claim 1, wherein the gain medium is formed of silicon carbide.

4. The system of claim 1, wherein the color center is a nitrogen-vacancy (NV) center.

5. The system of claim 1, wherein the color center is a divacancy.

6. The system of claim 1, further comprising a plurality of color centers formed in the gain medium based on a concentration to allow the gain to be higher than losses associated with a quality factor of the resonant cavity.

7. A system comprising:
a microring resonant cavity including a ringed gain medium;
a nitrogen-vacancy (NV) center, formed in the gain medium, including a lower laser level associated with a plurality of spin states that are affected by a magnetic field, wherein a gain associated with the system depends on the plurality of spin states, and the system is to produce light based on lasing by the resonant cavity in response to application of pump energy to pump the NV center, wherein an intensity of the produced light is affected by the magnetic field in the presence of microwave radiation; and
a waveguide optical subsystem to couple the light from the resonant cavity based on waveguide coupling.

8. The system of claim 7, wherein the NV center is negatively charged.

9. The system of claim 7, wherein the intensity of the produced light is based on exposure to the microwave radiation to affect populations of the plurality of spin states of the NV center.

10. The system of claim 7, wherein the microwave radiation is varied to identify information on the magnetic field affecting the NV center.

11. The system of claim 1, further comprising a reflector formed as a surface of the gain medium for free-space coupling.

12. The system of claim 7, wherein the waveguide optical subsystem is co-planar with the microring resonant cavity for planar waveguide coupling.

13. A method, comprising:
pumping a microring resonant cavity of a system based on a pump energy, wherein the resonant cavity includes a ringed gain medium;
producing light based on lasing by the resonant cavity in response to application of the pump energy to pump a color center formed in the gain medium and including a lower laser level associated with a plurality of spin states that are affected by the magnetic field, wherein a gain associated with the system depends on the plurality of spin states and an intensity of the produced light is affected by the magnetic field in the presence of microwave radiation.

14. The method of claim 13, further comprising splitting the plurality of spin states based on the magnetic field, wherein the plurality of spin states exhibit a plurality of different luminescences.

15. The method of claim 13, further comprising applying the microwave radiation to the system to affect the plurality of spin states, wherein the microwave radiation is varied based on sweeping a frequency of, and/or pulsing application of, the microwave radiation.
